(19) United States
(12) Patent Application Publication
(10) Pub. No.: US 2026/0049393 A1
(43) Pub. Date: Feb. 19, 2026

(54) PHYSICAL VAPOR DEPOSITION MODULE AND SYSTEM INCLUDING SAME

(71) Applicant: ASM IP Holding B.V., Almere (NL)

(72) Inventors: Paul Ma, Scottsdale, AZ (US); Tony Ping-Chen Chiang, Los Gatos, CA (US)

(21) Appl. No.: 19/298,415

(22) Filed: Aug. 13, 2025

Related U.S. Application Data
(60) Provisional application No. 63/684,250, filed on Aug. 16, 2024.

(51) Int. Cl. C23C 14/56; C23C 14/02; C23C 14/34

(52) U.S. Cl. CPC C23C 14/566; C23C 14/021; C23C 14/34; C23C 14/568

(57) ABSTRACT

Physical vapor deposition (PVD) systems and modules are disclosed. Exemplary systems can include one or more PVD modules, a degas module, a preclean module, and/or one or more ancillary modules. The ancillary modules can be used as cool down modules, metrology modules, or the like.

### CROSS-REFERENCE TO RELATED APPLICATIONS

This application is a nonprovisional of, and claims priority to and the benefit of, U.S. Provisional Patent Application No. 63/684,250, filed Aug. 16, 2024 and entitled “PHYSICAL VAPOR DEPOSITION MODULE AND SYSTEM INCLUDING SAME,” which is hereby incorporated by reference herein.

### FIELD OF DISCLOSURE

The present disclosure generally relates to physical vapor deposition systems and apparatus. More particularly, the disclosure relates to systems that include process modules for one or more steps of a physical vapor deposition process.

### BACKGROUND OF THE DISCLOSURE

Physical vapor deposition (PVD) processes can be used for a variety of applications. For example, PVD can be used in the manufacture of semiconductor devices, flat panel display devices, photovoltaic devices, microelectromechanical systems (MEMS), batteries, storage devices, and the like. By way of example, PVD can be used for advanced packaging applications during the manufacture, integration, and heterogenous integration of electronic devices, such as semiconductor devices and the like.

In some cases, PVD processing can include one or more pre-deposition processes and/or post-deposition processes. Such processes are often performed in dedicated chambers or modules and often process only a single substrate at a time. Such processing can be relatively expensive and time consuming.

Further, PVD processing often employs a dedicated PVD reactor for each material that is to be deposited onto a substrate for process performance reasons, such as, for example, deposition uniformity, deposition rate, film property uniformity, step coverage, step coverage uniformity, and/or particle performance. Such processing can also be relatively expensive and time consuming.

Accordingly, improved PVD systems and apparatus are desired. Any discussion of problems and solutions in this section has been solely for the purposes of providing a context for the present disclosure; such discussion should not be taken as an admission that any or all of the discussion was known at the time the invention was made.

### SUMMARY OF THE DISCLOSURE

Various embodiments of the present disclosure provide physical vapor deposition (PVD) systems and apparatus for depositing a PVD layer or layers on a substrate. The systems and apparatus described herein are suitable for use in a variety of applications, including, for example, advanced packaging, integration, and heterogenous integration for electronic devices. However, unless otherwise noted, the disclosure is not limited to such applications.

In accordance with various embodiments of the disclosure, a system is provided. An exemplary system includes a load lock chamber, a physical vapor deposition (PVD) module comprising two or more PVD chambers, a substrate handling chamber, at least one additional module, and a robot within the substrate handling chamber, the robot comprising an arm comprising one or more end effectors, each end effector configured to receive one or more substrates, and a controller configured to cause the robot to move the one or more substrates from the load lock chamber and between the physical vapor deposition module and the at least one additional module. For example, the controller can be configured to cause the robot to move the one or more substrates from the load lock chamber to chambers (e.g., PVD, preclean, and/or degas chambers) within the respective modules. In this context, a chamber refers to an area in which a substrate is processed. In accordance with examples of the disclosure, the at least one additional module comprises a surface modification module. For example, the at least one additional module can be or include a degas module, a preclean module, or both. In some cases, the controller is configured to cause the robot to move the one or more substrates from the load lock chamber to a degas module, from the degas module to a preclean module, and from the preclean module to the PVD module; or from the load lock chamber to a degas module and from the degas module to the PVD module; or from the load lock chamber to a preclean module and from the preclean module to the PVD module. In some cases, the robot is configured to move two or more substrates.

The degas module can include two or more degas chambers. The two or more degas chambers can be at least partially separated by a wall between the degas chambers. In accordance with examples of the disclosure, the degas module comprises a lamp to heat the one or more substrates. The lamp can provide one or more of infrared light or ultraviolet light to a surface of a substrate to provide desired heat to the substrate. Additionally or alternatively, a susceptor, also referred to herein as a pedestal, within the degas module can include a heater, such as a resistive heater. A temperature within one or more of the degas chambers and/or within the degas module can be controlled using one or more temperature sensors, such as thermocouples, infrared sensors, or the like, within one or more of the degas chambers. The degas module can include a turbomolecular pump, a cryopump, or both coupled to one (e.g., each) or two or more degas chambers.

The preclean module can similarly include two or more preclean chambers. In accordance with examples of the disclosure, one or more (e.g., each) of the preclean chambers includes a capacitively coupled plasma (CCP) chamber or an inductively coupled plasma (ICP) chamber. In the case of a CCP chamber, the susceptor can be coupled to a plasma power source that provides suitable power to produce a plasma within the preclean chamber. In the case of ICP preclean chamber, a coil can be coupled to a plasma power source that provides suitable power to produce a plasma within the preclean chamber; the coil can be around a chamber, at a top of the chamber, or both. In accordance with further examples, the preclean module includes a chiller to cool a cooling fluid. In accordance with further examples, a susceptor within a preclean chamber includes a conduit to receive the cooling fluid to cool a substrate to a temperature of, for example, at least 0° C. or lower. Additional configurations of preclean chambers are described below. In some embodiments, the substrate is cooled to −10° C. or lower.

In accordance with further examples of the disclosure, the two or more PVD chambers (e.g., each) include a sputtering chamber. The PVD module can include a shield between at least two of the two or more PVD chambers. For example, each of the two of the two or more PVD chambers can include a shield. The two or more PVD chambers can be or include, for example, a DC sputter reactor, a pulsed DC sputter reactor, a HiPIMS (high power impulse magnetron sputtering) sputter reactor, an RF sputter reactor, or any combination thereof. The two or more PVD chambers can be coupled to independent exhaust sources (e.g., vacuum pumps) or can be coupled to a shared exhaust source. In some embodiments, a pressure and/or relative pressure in each of the two or more PVD chambers can be independently controlled. In other embodiments, the process gas composition and/or relative gas composition in each of the two or more PVD chambers can be independently controlled.

In accordance with further examples of the disclosure, a system can include one or more of a cool down module and/or a metrology module. Such modules can be in addition to or in place of one of the other modules noted above.

In accordance with further examples of the disclosure, a PVD module is provided. The PVD module can include, for example, a first PVD chamber comprising a first target material and a first susceptor, a second PVD chamber comprising a second target material and a second susceptor, a shield between the first PVD chamber and the second PVD chamber, and a (e.g., first) power supply to provide power to the first target and/or the second target. In some cases, the first target material is different than the second target material. Such a module allows relatively rapid deposition of multiple materials within a single module. In some cases, the first target material is the same as the second target material to improve throughput especially when the PVD process step is rate limiting. In some cases, each of the first and second PVD chamber has its own power supply to provide power to the first and second target respectively. In some cases, one or more of the PVD chambers includes a collimator. In some cases, a distance between a substrate on the first susceptor and the first target is greater than or equal to a diameter of the substrate. In accordance with some examples, the first PVD chamber and the second PVD chamber are coupled to an exhaust source. In some cases, a pressure within the first PVD chamber and a pressure within the second PVD chamber can be independently controlled.

Both the foregoing summary and the following detailed description are exemplary and explanatory only and are not restrictive of the disclosure or the claimed invention.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a system in accordance with various embodiments of the disclosure.

FIG. 2 illustrates another view of the system of FIG. 1.

FIG. 3 illustrates another system in accordance with exemplary embodiments of the disclosure.

FIG. 4 illustrates a process module in accordance with exemplary embodiments of the disclosure.

FIG. 5 illustrates a process chamber in accordance with further exemplary embodiments of the disclosure.

FIG. 6 to FIG. 9 illustrate exemplary configurations of a system in accordance with further exemplary embodiments of the disclosure.

FIG. 10 illustrates a degas chamber in accordance with further exemplary embodiments of the disclosure.

FIG. 11 illustrates a preclean chamber in accordance with further exemplary embodiments of the disclosure.

FIG. 12 to FIG. 15 illustrate physical vapor deposition chambers in accordance with further exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

As set forth in more detail below, various embodiments of the disclosure relate to systems, components thereof, and to methods of using the systems and components that allow for relatively rapid physical vapor deposition of one or more materials onto a substrate. The systems and components can be used in a variety of applications, such as the applications noted herein.

Systems in accordance with various examples of the disclosure include one or more modules for processing substrates. Each module can include one or two or more chambers for processing substrates. For example, modules can include one, two, or four chambers.

As used herein, the term substrate may refer to any underlying material or materials, including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can additionally or alternatively include various features, such as recesses, lines, and the like formed within or on at least a portion of a layer of the substrate. In accordance with particular examples of the disclosure, the substrate includes devices and the processes described herein are used for advanced packaging processes. In some embodiments, the substrate may be a die, dielet, chip, chiplet, passive interposer, active interposer, glass substrate, organic substrate, ceramic substrate, wafers, and/or panel.

In some embodiments, the term film refers to a layer extending in a direction perpendicular to a thickness direction. In some embodiments, layer refers to a material having a certain thickness formed on a surface or a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, the term gas may refer to material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution device, such as a showerhead, other gas distribution device, or the like, may be used for, e.g., sealing the reaction space or separating the reaction space from another reaction space.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, etc. in some embodiments. For example, the term about can refer to +/−20, 10, 5, 2, or 1 percent of a value. Further, in this disclosure, the terms including, constituted by and having can refer independently to typically or broadly comprising, comprising, consisting essentially of, or consisting of in some embodiments. In accordance with aspects of the disclosure, any defined meanings of terms do not necessarily exclude ordinary and customary meanings of the terms.

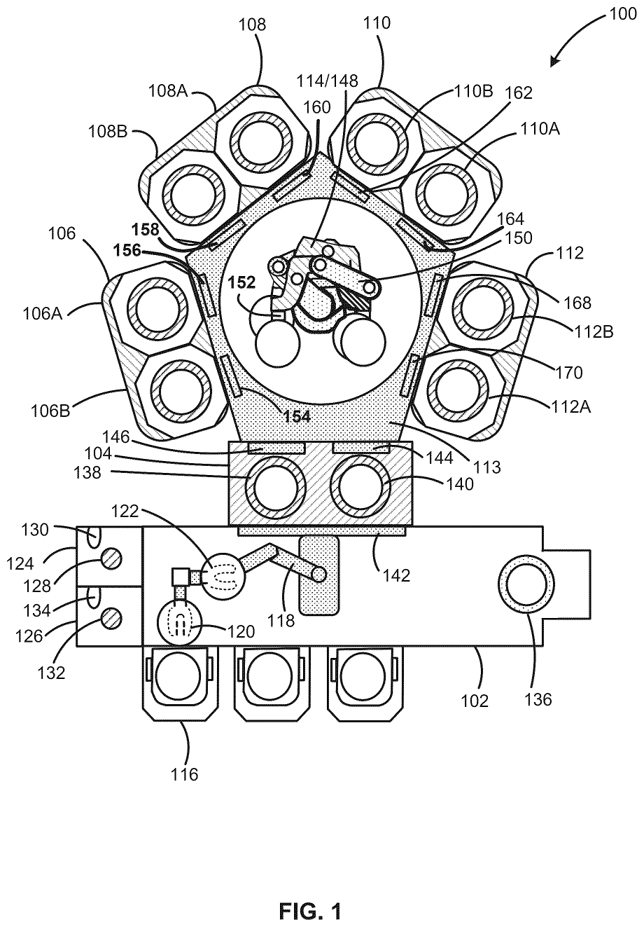

Turning now to the figures, FIG. 1 illustrates a system 100 in accordance with embodiments of the disclosure. In the illustrated example, system 100 includes a front end module 102, a load lock apparatus 104, modules 106-112, a substrate handling chamber 113, and a robot 114 within substrate handling chamber 113.

As set forth in more detail below, system 100 or other systems described herein can be configured in a variety of ways. System 100 is described in connection with particular exemplary modules. However, unless otherwise noted, systems in accordance with the disclosure are not so limited.

Front end module 102 is provided with a load port 116 and a first robot 118. A FOUP is placed on load port 116. In the illustrated example, first robot 118 includes a first end effector 120 and a second end effector 122. First end effector 120 and second end effector 122 can be, for example, a vacuum suction apparatus or an electrostatic apparatus that retains a substrate, such as a wafer. First robot 118 can be referred to as a “FERB (Front End RoBot).” The illustrated exemplary first robot 118 is an articulated robot that can move first end effector 120 and second end effector 122 separately. First robot 118 can convey one or two substrates.

In the illustrated example, system 100 includes aligners 124, 126. Aligners 124 and 126 are attached to front end module 102. Aligner 124 is provided with a turntable 128 and a sensor 130 that detects a substrate placed on the turntable 128. Aligner 126 is provided with a turntable 132 and a sensor 134 that detects a substrate placed on the turntable 132. Aligners 124 and 126 are constructed and arranged to detect a center of the substrate and/or a notch or orientation flat of the substrate using any suitable method. Front end module 102 can also include a cooling stage 136 used to cool the substrate.

Load lock apparatus 104 is attached to front end module 102. Load lock apparatus 104 includes one or more load locks 138, 140 to load or unload a substrate before or after processing. A gate valve 142 is provided between the load lock apparatus 104 and front end module 102. Load lock apparatus 104 further includes a gate valve 144 and a gate valve 146 between respective load locks 138, 140 and substrate handling chamber 113. In the illustrated example, load lock apparatus 104 can accommodate two substrates. Load lock apparatus 104 is provided within a moving range of first robot 118.

Substrate handling chamber 113 is connected to load lock apparatus 104. In the illustrated example, substrate handling chamber 113 has a polygonal shape in a plan view, one side face or facet of which is in contact with the load lock apparatus 104. A (e.g., second) robot 114 is provided in substrate handling chamber 113. Robot 114 can be referred to as a “BERB (Back End RoBot)” and can include a first part 148 and a second part 150. Each part 148, 150 includes a dual arm substrate/wafer handling arm 152 having two ends to convey two substrates. Each end can be or include an end effector as described above.

Modules 106-112 are connected to side faces or facets of substrate handling chamber 113, respectively (e.g., in a one-to-one correspondence). Substrate handling chamber 113 is partitioned from modules 106-112 by respective gate valves 154-164, 168, 170. In the illustrated example, each module 106-112 is a DCM (dual chamber module). Module 106 includes a first processing chamber 106A and a second processing chamber 106B. Module 108 includes a first processing chamber 108A and a second processing chamber 108B. Module 110 includes a first processing chamber 110A and a second processing chamber 110B. Module 112 includes a first processing chamber 112A and a second processing chamber 112B. Thus, the four different modules that each include two processing chambers are illustrated. Exemplary modules are discussed in more detail below. As noted above, a chamber can refer to an area in which one or more substrates are processed. For example, a single substrate can be processed within a chamber.

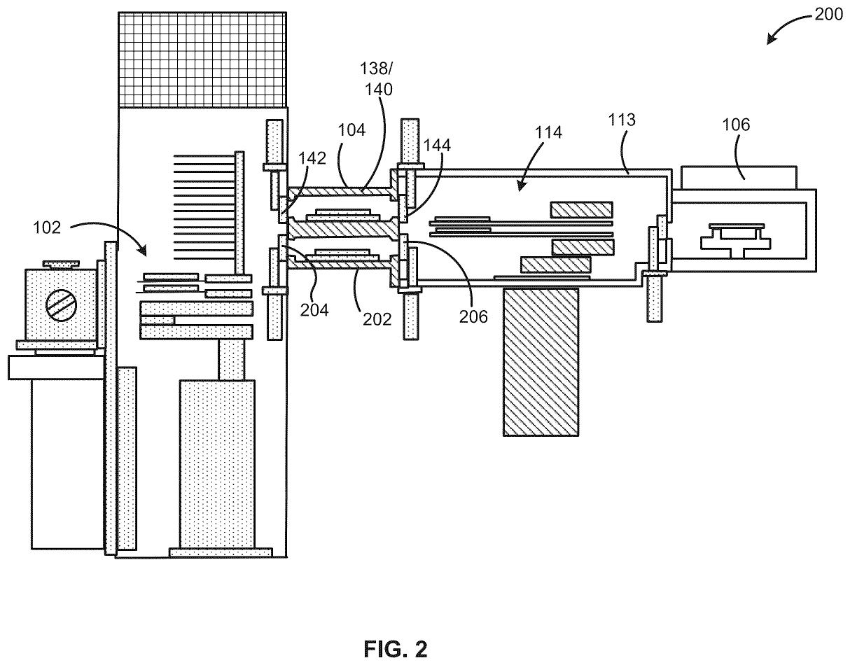

FIG. 2 illustrates a cross-sectional view of a system 200. System 200 can be the same or similar to system 100, with some components moved for ease of illustration. FIG. 2 illustrates a load lock apparatus 104 that includes additional load locks 202, which are located beneath load locks 138, 140, and which can be the same as load locks 138, 140. Load lock apparatus 104 can suitably include additional gate valves 204, 206 corresponding to the additional load locks 202.

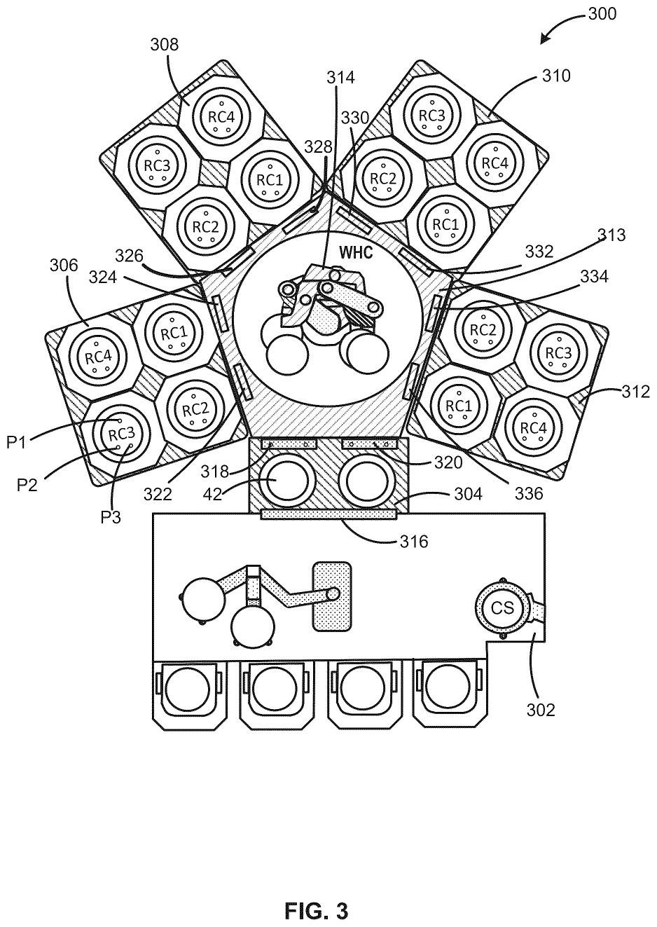

FIG. 3 illustrates another system 300 in accordance with examples of the disclosure. System 300 is similar to system 100, except system 300 includes modules that can process up to four substrates at a time.

Similar to system 100, system 300 includes a front end module 302, a load lock apparatus 304, modules 306-312, substrate handling chamber 313, and a robot 314 within substrate handling chamber 313.

Front end module 302, load lock apparatus 304, substrate handling chamber 313, and robot 314 can be as described above. Further, system 300 can include gate valves 316-336 and a cooling station CS, which can be the same or similar to those described above.

Modules 306-312 can be modules configured to process a plurality of substrates. In the illustrated example, each module 306-312 includes four chambers. The four chambers are denoted as RC1, RC2, RC3, RC4. As described below, various processes can be applied to a substrate within a chamber.

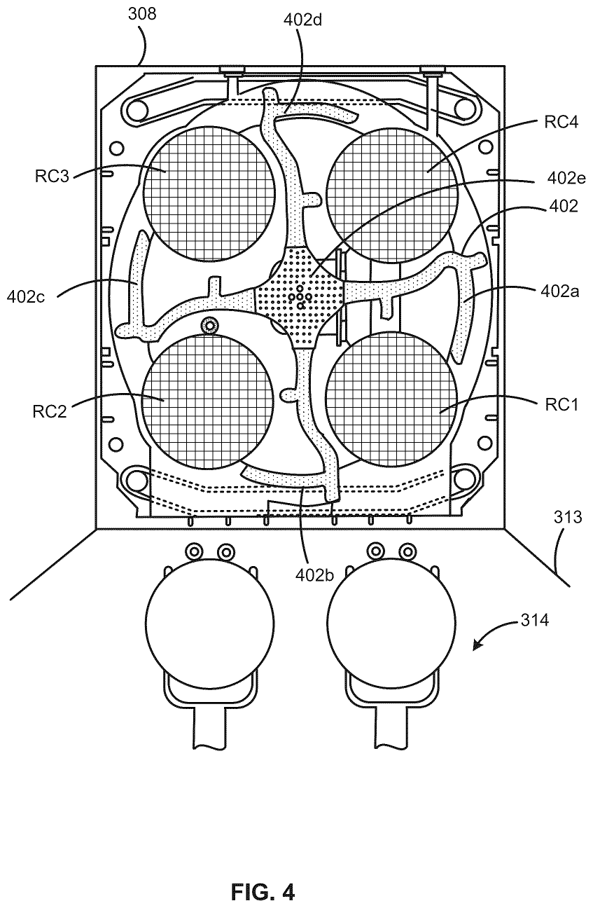

FIG. 4 illustrates a plan view of an example of the configuration module 308 and a portion of substrate handling chamber 313. Module 308 includes a first chamber RC1, a second chamber RC2, a third chamber RC3, and a fourth chamber RC4. Substrate handling chamber 313 is located at a position closer to the first chamber RC1 and the second chamber RC2 than the third chamber RC3 and the fourth chamber RC4. Substrate handling chamber 313 intercommunicates directly or via a gate valve with the first chamber RC1 and the second chamber RC2.

A transfer arm 402 is provided inside module 308. Transfer arm 402 includes, for example, a first arm 402a, a second arm 402b, a third arm 402c, a fourth arm 402d, and a shaft 402c. First arm 402a, second arm 402b, third arm 402c, and fourth arm 402d are supported by shaft 402e, and rotated by rotation of the shaft 402e. First to fourth arms 402a, 402b, 402c, and 402d can be located between the chambers or inside a specific chamber according to the rotational state of the shaft 402e. Transfer arm 402 is used to provide a substrate onto a susceptor and take out a substrate on the susceptor. Transfer arm 402 can serve as a rotation arm for moving a substrate in one of the first to fourth chambers RC1, RC2, RC3, and RC4 into another chamber. Such a rotation arm rotates, for example, counterclockwise by 180° in one operation. Modules 306, 310, and 312 may be configured to have the same or similar configuration as module 308.

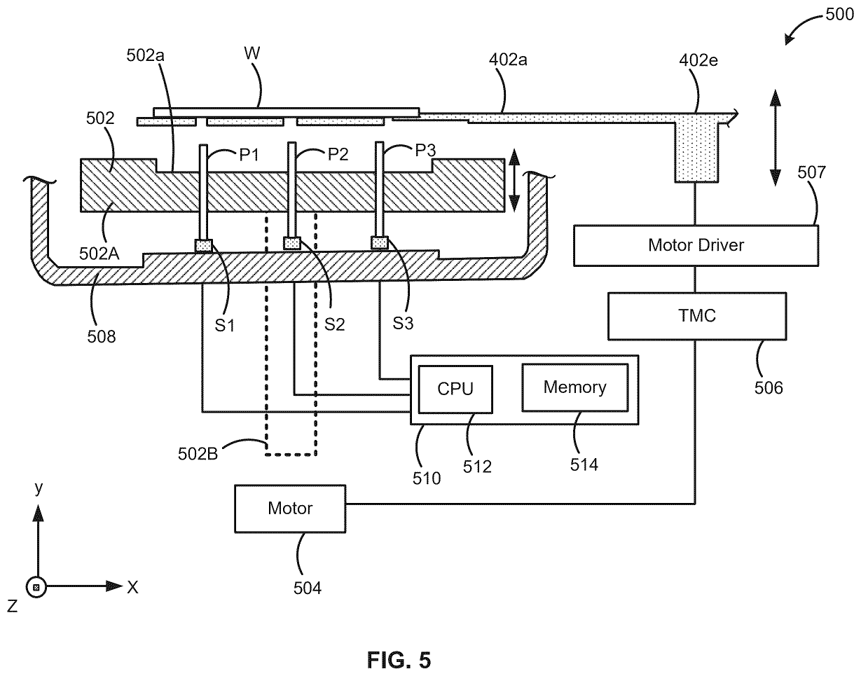

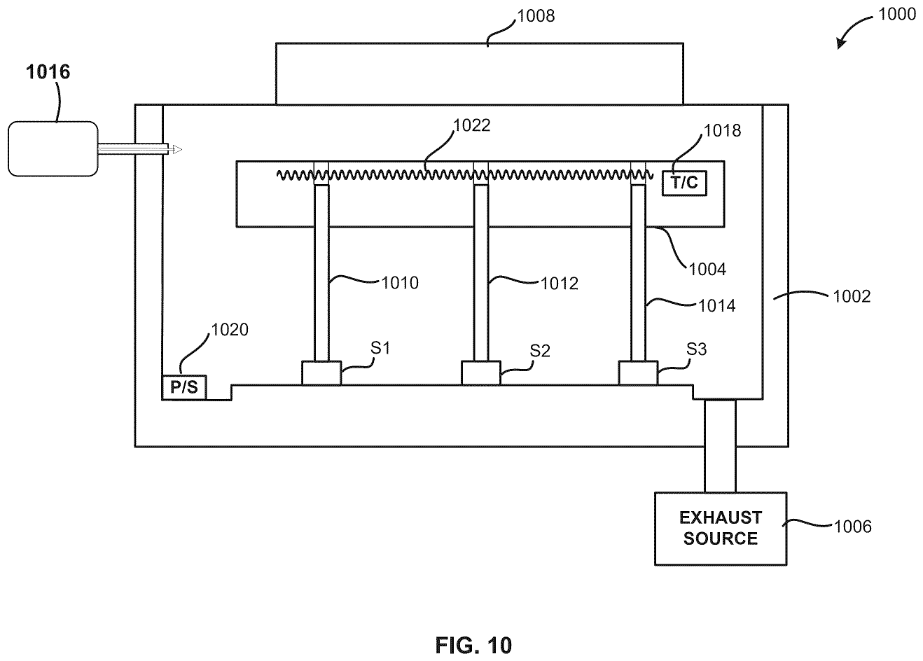

FIG. 5 illustrates a cross-sectional view of an exemplary chamber 500 suitable of one or more modules of system 100 and/or system 300. Chamber 500 includes a susceptor 502 that is configured to receive and retain a substrate W during processing. Susceptor 502 includes a substrate support 502A and a shaft portion 502B. A substrate pocket 502a may be formed in the substrate support 502A. Shaft portion 502B receives the force of a motor 504 under the control of a transfer module controller (TMC) 506 and optionally a motor driver 507, and can move upward or downward in a vertical direction, that is, in z positive and negative directions. The upward and downward movement of the shaft portion 502B also makes substrate support 502A move upward and downward. According to an example, susceptor pins P1, P2, and P3 are fixed to a chamber wall 508 via sensors S1, S2, and S3. The sensors S1, S2, and S3 may be provided at different positions for detecting the contact or non-contact of the substrate with the susceptor pins P1, P2, and P3. The susceptor pins P1, P2, and P3 are configured to protrude from the upper surface of the susceptor 502 or be positioned below the upper surface of the susceptor 502 according to the height of the susceptor 502. FIG. 5 shows a state where the susceptor pins P1, P2, and P3 protrude from the upper surface of the susceptor 502. The number of susceptor pins to be provided to one susceptor 502 may be three or more. A detection result can be acquired by a controller 510. Controller 510 can include, for example, a CPU 512 and a memory 514. Controller 510 or another controller can perform additional or alternative functions as described below. More detailed examples of various modules and chambers are provided below in connection with FIG. 10 to FIG. 15.

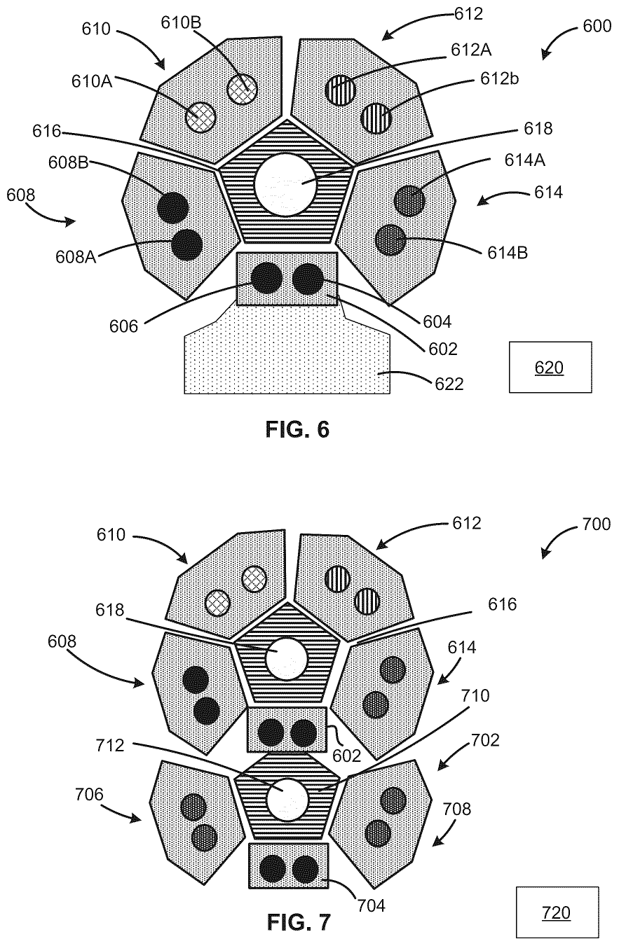

FIG. 6 to FIG. 9 illustrate various configurations of systems in accordance with examples of the disclosure. The systems illustrated in FIG. 6 to FIG. 9 include a PVD module and other modules that may be used in PVD processes. These systems are merely illustrative of examples of the disclosure. Unless otherwise noted, examples of the disclosure are not limited to the specific configurations illustrated below.

FIG. 6 illustrates a system 600 that includes a load lock apparatus 602 that includes load lock chambers 604 and 606, a degas module 608 comprising degas chambers 608A, 608B, a preclean module 610 comprising preclean chambers 610A, 610B, a physical vapor deposition (PVD) module 612 comprising two or more PVD chambers 612A, 612B, a substrate handling chamber 616, a robot 618 within substrate handling chamber 616, and a controller 620. As described above, robot 618 can include an arm comprising one or more end effectors, each end effector configured to receive one or more substrates. Controller 620 is configured to cause robot 618 to move the one or more substrates from a load lock chamber 604 or 606 to degas module 608, from the degas module 608 to the preclean module 610, and from preclean module 610 to PVD module 612. In addition, controller 620 can be configured to move substrates from any of modules 608-612 to module 614 and then to any other module or to load lock apparatus 602. Controller 620 can be the same or similar to controller 510 described above. System 600 can also include a front end module 622 that can be the same or similar to the front end modules describe above. System 600 also includes a module 614 that includes chambers 614A and 614B. Chambers 614A and 614B can be used for a variety of purposes, such as degas, preclean, PVD, cool down, metrology, or the like. In some cases, module 614 can be a cool down module or a metrology module.

FIG. 7 illustrates another system 700 in accordance with further examples of the disclosure. System 700 is similar to system 600, except system 700 includes an additional section 702 that includes a load lock apparatus 704, process modules 706, 708, a second substrate handling chamber 710, a second substrate robot 712, and a controller 720.

Load lock apparatus 704 can be the same or similar to load lock apparatus 602 described above. Similarly, second substrate handling chamber 710, and second substrate robot 712 can be the same or similar to substrate handling chamber 616 and robot 618.

Process modules 706 and 708 can be configured as desired. For example, modules can be or include additional degas, preclean or PVD modules, in any combination. In accordance with some examples of the disclosure, one or more of process modules 706, 708 can be or include a metrology module and/or cool down stations (also referred to herein as a chamber) or combinations thereof. By way of examples, at least one process module 706 or 708 can include a metrology station and/or a cool down station. Exemplary metrology stations can measure film thickness and/or composition, measure substrate warpage, determine whether a crack exists, and/or determine stress within the substrate and/or of a deposited film. One or more metrology stations can be coupled to controller 720 to provide process feedback. Controller 720 can then provide an alert, stop a process, and/or manipulate one or more process conditions based on a measurement. For example, a measured film thickness that is below a target value could indicate an aging target and an appropriate signal can be sent to a user interface of a system, or other alert can be sent, and/or a process condition, such as process time can be automatically adjusted using controller 720. Similarly, if warpage is detected, a power or power duty cycle can be (e.g., automatically) adjusted.

Controller 720 can be the same or similar to controller 620. For example, controller 720 can be configured to cause robot 618 to move as described above. Additionally or alternatively, controller 720 can cause second substrate robot 712 to move substrates between load lock apparatus 704, process module 706, process module 708, and/or load lock apparatus 602 in any order and in any combination. Controller 720 can additionally be configured to perform the functions of controller 620 described above.

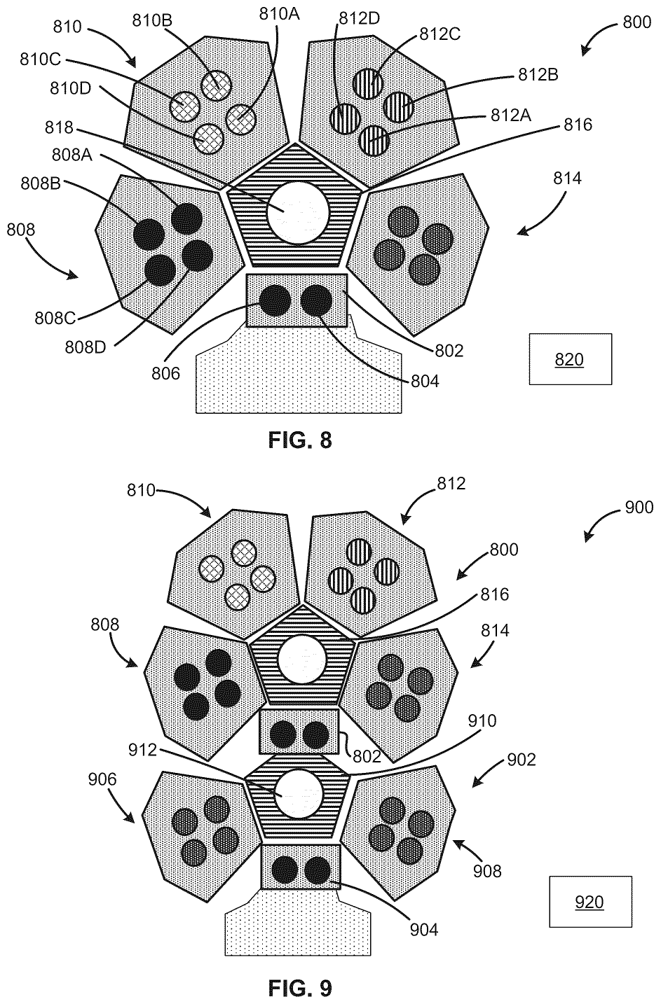

FIG. 8 illustrates another exemplary system 800 in accordance with the disclosure. System 800 can be a particular example system 200.

System 800 includes a load lock apparatus 802 that includes load locks 804 and 806, a degas module 808 comprising degas chambers 808A, 808B, 808C, 808D; a preclean module 810 comprising preclean chambers 810A, 810B, 810C, 810D; a physical vapor deposition (PVD) module 812 comprising two or more PVD chambers 812A, 812B, 812C, 812D; a substrate handling chamber 816, and a robot 818 within substrate handling chamber 816. System 800 can also include a module 814, which can include chambers, such as chambers described above in connection with module 614.

System 800 also include a controller configured to move one or more substrates as described above. For example, controller 820 can be similar to controller 620 as described above and can additionally be configured to move substrates using a transfer arm, such as transfer arm 402, described above.

FIG. 9 illustrates another system 900 in accordance with further examples of the disclosure. System 900 is similar to system 800, except system 900 includes an additional section 902 that includes a load lock apparatus 904, process modules 906, 908, a second substrate handling chamber 910, a second substrate robot 912, and a controller 920. Additional section 902 can be similar to additional section 702, except process modules 706 and 708 are configured to handle up to four substrates as described above in connection with system 200. Controller 920 can be the same as controller 820. Additionally or alternatively, controller 920 can cause second substrate robot 912 to move substrates between load lock apparatus 904, process module 906, process module 908, and/or load lock apparatus 904 in any or order and in any combination.

FIG. 10 to FIG. 15 illustrate various chambers in accordance with examples of the disclosure.

FIG. 10 illustrates a degas chamber 1000 in accordance with examples of the disclosure. Degas chamber 1000 includes a chamber wall 1002, a susceptor 1004, an exhaust source 1006, and a heat source 1008.

Chamber wall 1002 can be formed of any suitable material. For example, chamber wall 1002 can be formed of aluminum and/or stainless steel, depending on the application need.

Susceptor 1004 can be the same or similar to susceptor substrate support 502A described above. As described above in connection with chamber 500, degas chamber 1000 can include lift pins 1010-1014, which can be the same or similar to lift pins P1-P3. Further, degas chamber 1000 can include sensors S1-S3, described above. In some cases, susceptor 1004 includes a heater 1022, such as a resistive heater, to heat a substrate during a degas process.

Exhaust source 1006 can include a turbomolecular pump, a cryopump, or both and optionally a water pump and/or a titanium sublimation pump coupled to one or two or more degas chambers. Exhaust source 1006 can be configured to provide a sub-atmospheric pressure within degas chamber 1000. In some cases, an operating pressure within degas chamber 1000 is less than or equal to 10⁻⁵ Torr base pressure, less than or equal to 10⁻⁶ Torr, less than or equal to 10⁻⁷ Torr, or less than or equal to 10⁻⁸ Torr for efficient pump out of desorbed species.

In some embodiments, degas chamber 1000 includes a gas source 1016 to provide a gas (e.g., N₂, Ar, He, or other inert gas) during a degas process. In some embodiments, a hydrogen containing gas is provided during a degas process. In other embodiments, no active gas flow is performed during a degas process.

Degas chamber 1000 can also include one or more temperature sensors 1018 and/or pressure sensors 1020. Temperature sensors 1018 and/or pressure sensors 1020 can be coupled to a controller as described herein and can be used to regulate a temperature and/or pressure within degas chamber 1000. Temperature sensors can be or include, for example, a thermocouple, an IR sensor, a pyrometer outside the reaction chamber, or the like.

Heat source 1008 can be or include one or more lamps. Exemplary lamps include IR and UV lamps, which can have wavelengths tailored to materials of interest (e.g., materials to be degassed).

Heat source 1008 and/or heater 1022 can be used to heat a substrate to a desired temperature. For example, a process temperature can be maintained between 100° C. and 300° C. or between 100° C. and 200° C. during a degas process.

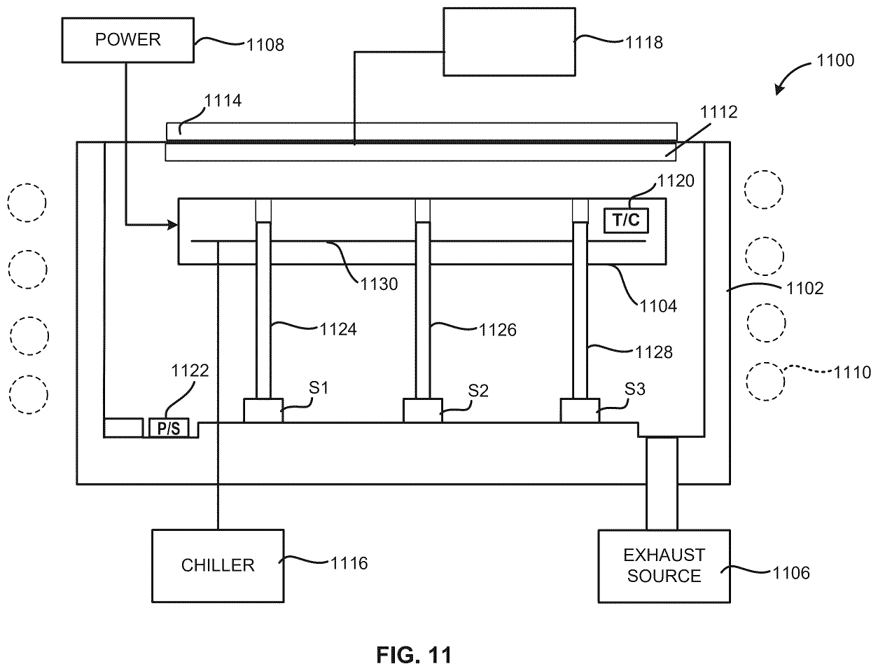

FIG. 11 illustrates a preclean chamber 1100 suitable for use in systems described herein. Preclean chamber 1100 includes a chamber wall 1102, a susceptor 1104, an exhaust source 1106, and a power source 1108.

Chamber wall 1102, susceptor 1104, and exhaust source 1106 can be the same or similar to those described above in connection with FIG. 10.

In accordance with examples of the disclosure, preclean chamber 1100 can be configured as a plasma reactor or chamber. In the illustrated example, preclean chamber 1100 is configured as capacitively coupled plasma chamber with power source 1108 providing plasma power to susceptor 1104 to produce a plasma within preclean chamber 1100. In this case, a frequency of the power can be, for example, 13.56 MHz or higher and the power can be between about 20 W and about 5000 W for a 300 mm diameter substrate. In some embodiments, the power is between about 50 W and 2500 W. In other embodiments, the power is between about 100 W and 1000 W. A gas distribution device 1112, such as a showerhead device, can be used as a second electrode of a capacitively coupled plasma chamber.

In accordance with additional or alternative embodiments, preclean chamber 1100 can be configured as an inductively coupled plasma chamber. In this case, preclean chamber 1100 can include a coil 1110 illustrated in dashed lines. Coil 1110 can be about chamber wall 1102 as illustrated, at a top of preclean chamber 1100, or both. In this case, a frequency of a plasma power from power source 1108 can be 2 MHz or higher and the inductive plasma power can be between about 20 W and about 5000 W. In some embodiments, the power is between about 50 W and 3000 W. In other embodiments, the power is between about 100 W and 1500 W.

In accordance with yet additional embodiments of the disclosure, a physical magnet and/or electromagnet array, [i.e., magnetron] 1114 on the chamber top (e.g., parallel with susceptor 1104) can be used to improve plasma uniformity, density.

In some embodiments, the magnetron is used as part of a capacitively coupled plasma configuration. In other embodiments, the magnetron is used as part of an inductively coupled plasma configuration.

In some cases, it may be desirable to cool a substrate to below room temperature during a preclean process. Accordingly, preclean chamber 1100 can include a chiller 1116 and a cooling fluid, such as Galden, helium, or the like, to cool a substrate or susceptor temperature to less than 0° C., less than −10° C., less than −20° C., or less than −30° C., and may be as low as about −70° C. Chiller 1116 is used to cool the cooling fluid to a desired temperature. The cooling fluid can be provided to a conduit 1130 within susceptor 1104 and circulated back to chiller 1116.

Preclean chamber 1100 can also include a gas source 1118 to provide a process gas, such as Ar, to generate ions for physical sputtering. Additionally or alternatively, gas source 1118 can provide He, H₂, N₂, and/or Ar in any combination.

As illustrated, preclean chamber 1100 can include temperature sensors 1120, pressure sensors 1122, lift pins 1124-1128, and sensors S1-S3, which can be as described above. Various components of preclean chamber 1100 can be controlled by a controller, such as a controller described herein.

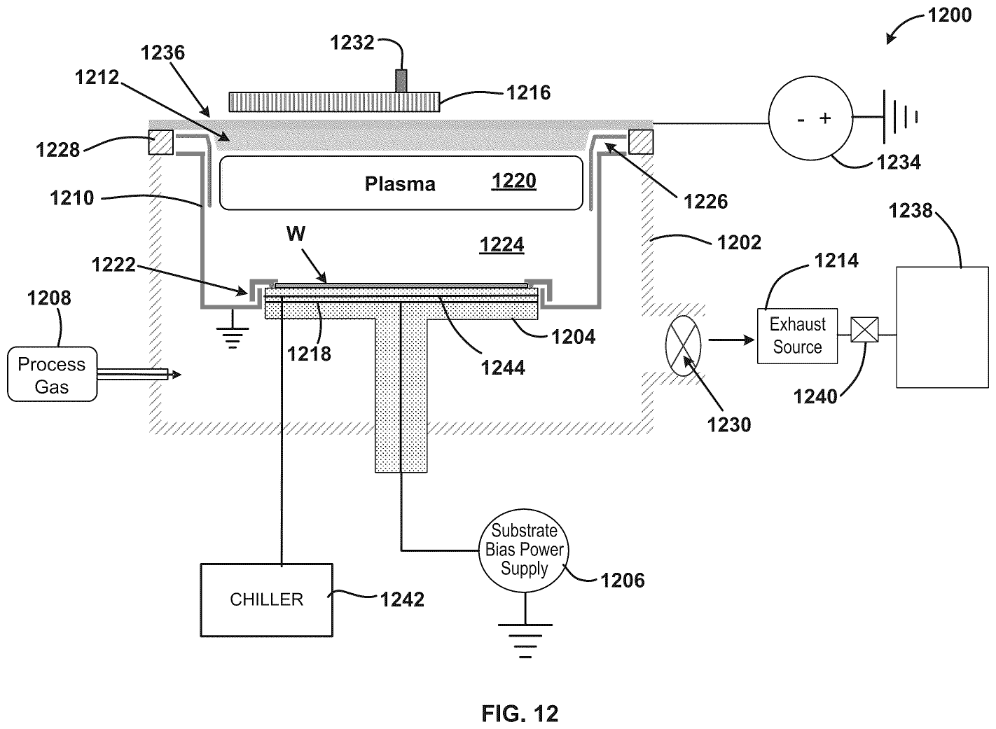

FIG. 12 to FIG. 15 illustrate exemplary PVD chambers in accordance with examples of the disclosure. The exemplary PVD chambers can include a sputtering chamber also referred to herein as a sputter reactor. Exemplary PVD chambers can be used in a variety of applications, including, for example, deposition of backside metal (BSM), deposition of under bump metal (UBM), deposition of barriers, liners, and/or seed layers for through silicon via (TSV), deposition of barriers, liners, and/or seed layers for through glass via (TGV), and the like.

FIG. 12 illustrates a PVD chamber 1200. PVD chamber 1200 can be configured as a DC sputter reactor, a pulsed DC sputter reactor, a HiPIMS (high power impulse magnetron sputtering) sputter reactor, an RF sputter reactor, or any combination thereof.

In the illustrated example, PVD chamber 1200 includes a chamber wall 1202, a susceptor 1204, a substrate bias power supply 1206, a process gas source 1208, a shield 1210, a spacer ring 1228, a target 1212, a target backing plate 1236, a magnetron 1216, and an exhaust source 1214.

Chamber wall 1202 can be the same or similar to chamber wall 1002 described above. In accordance with examples of the disclosure, chamber wall 1202 is formed of aluminum and/or stainless steel.

Susceptor 1204 can be similar to susceptors described above. For example, susceptor 1204 can include a heater and/or a cooling conduit as described above. In accordance with examples of the disclosure, susceptor 1204 includes an electrode 1218 that is electrically coupled to substrate bias power supply 1206 to bias a substrate W during operation of PVD chamber 1200. In accordance with examples of the disclosure, susceptor 1204 is configured to move up and down as described above in connection with FIG. 5. The up and down movement can be used to control target 1212 to a substrate W process spacing. In some cases, susceptor 1204 can be configured as an electrostatic chuck.

In some cases, it may be desirable to cool a substrate to below room temperature during a PVD process. Accordingly, PVD chamber 1200 can include a 1242 and a cooling fluid (not shown), such as Galden, helium, or the like, to cool a substrate W or susceptor 1204 temperature to less than 0° C., less than −10° C., less than −20° C., or less than −30° C., and may be as low as about −70° C. The chiller can be used to cool the cooling fluid to a desired temperature. The cooling fluid can be provided to a conduit 1244 within susceptor 1204 and circulated back to chiller 1242.

In the illustrated example, PVD chamber 1200 includes a clamp and/or cover and/or shadow ring illustrated as Clamp/cover/shadow ring 1222. Clamp/cover/shadow ring 1222 can be used to protect an edge of susceptor 1204 from unwanted deposition, can minimally contact the periphery of substrate W, can optionally not contact the substrate but create a shadow ring to control deposition on substrate edge, and/or can optionally modulate the gas conductance into and out of a process region 1224 above substrate W. In other embodiments, the Clamp/cover/shadow ring 1222 can be used to define a no deposition zone on the peripheral front side surface of the substrate. To release Clamp/cover/shadow ring 1222 on lower shield to enable substrate transfer (lift pins not shown; lift pins are recessed during process positions but are exposed during release/substrate transfer position), susceptor 1204 can be (e.g., fully) lowered. The susceptor 1204 is raised and the Clamp/cover/shadow ring 1222 is picked up by the susceptor 1204 during process position. In this position, lift pins are recessed.

substrate bias power supply 1206 provides desired power to electrode 1218 during processing. In the illustrated example, substrate bias power supply 1206 provides desired bias power to electrode 1218 and/or can be used to produce a secondary plasma (not shown). For example, a power provided by substrate bias power supply 1206 to electrode 1218 can be between 20 W and 5000 W and a frequency of the power can be about 13.56 MHz or 60 MHz. A frequency of substrate bias power supply 1206 and/or phase can be selected to minimize any crosstalk from other power sources. In some embodiments, the substrate bias power supply 1206 to electrode 1218 can be between 50 W and 3000 W. In other embodiments, the substrate bias power supply 1206 to electrode 1218 can be between 50 W and 1500 W.

The bias can be applied to facilitate desired step coverage of the deposited material. substrate bias power supply 1206 can be used to, for example, modulate ion energy, flux, or the like. substrate bias power supply 1206 can be coupled to a controller, such as a controller described herein.

Process gas source 1208 can provide one or more process gases to process region 1224. Exemplary process gases include Ar, Xe, Kr, N₂, O₂ and the like. In some cases, a reactive gas, such as N₂ and/or O₂, is provided by process gas source 1208 and can be provided in conjunction w/Ar, Xe, Kr, and the like. Although not separately illustrated, process gas source 1208 can include various valves and/or mass or volume flow controllers, which can be connected to a controller, such as a controller described herein. In accordance with examples of the disclosure, each source gas from process gas source 1208 is independently controlled (e.g., using mass or volume flow meters).

Shield 1210 and upper shield 1226 can be used to provide isolation of process region 1224 of PVD chamber 1200. Shield 1210 can suitably be formed of metal, such as aluminum, stainless steel, or the like, and can be grounded. As illustrated, PVD chamber 1200 can also include an upper shield 1226 and spacer ring 1228 between upper shield 1226 and shield 1210. Upper shield 1226 can be floating. In some embodiments, metal can be used or used in portions of shield 1210 and/or areas around PVD chamber 1200 and/or magnetron 1216 to minimize potential magnetic interference to, from, and/or between adjacent reactors, chambers and/or modules.

Shield 1210 and upper shield 1226 can be about a periphery of substrate W and at least a top surface of susceptor 1204. In some cases, shield 1210 and upper shield 1226 can be concentric about at least the top surface of susceptor 1204. In some cases, each chamber includes one or both shield 1210 and upper shield 1226.

Target 1212 can be or include a variety of materials that are to be deposited onto a substrate surface. By way of examples, target 1212 can include a metal, such as one or more of Ti, Ta, TiW, Cu, Co, Mo, Ru, Ni, NiV, Al, W, Au, Ag and/or combinations thereof. In some cases, target 1212 can include a semi-metal, such as graphite or α-Sn. In some cases, target 1212 includes an insulating material or an oxide. Examples include neodymium oxide (Nd₂O₃), alumina zinc oxide (AZO), indium tin oxide (ITO) and mixed oxide sputtering targets such as lanthanum nickel oxide (LaNiO₃) and yttrium iron granite (YIG). In such cases, RF sputter may be desirable.

In accordance with examples of the disclosure, each PVD chamber within a module may include the same target material. In other cases, at least one target material in a PVD chamber in a module is different from a target material in another PVD chamber. Use of different target materials within a module enables local film stack integration (if different). Such configurations can also improve chamber availability in case certain chambers need to be serviced. In cases where multiple target materials are the same, throughput can be improved.

Exhaust source 1214 can be or include any exhaust source as described herein. By way of example, exhaust source 1214 can be or include a cryogenic pump, a turbomolecular pump, any combinations thereof, and optionally a water pump and/or a titanium sublimation pump if a turbomolecular pump is used. A variable conductance device 1230 (e.g., butterfly valve, multi-position gate valve, or the like) can be controlled by a controller, such as a controller described herein.

In accordance with some examples of the disclosure, exhaust source 1214 can be shared between two or more (e.g., 2, 3, or 4) PVD chambers, such as PVD chamber 1200 and a second PVD chamber 1238 that can be within the same PVD module. In some embodiments, a pressure within the first PVD chamber 1200 and a pressure within the second PVD chamber 1238 can be independently controlled by, for example, using variable conductance device 1230 and 1240. In other cases, each PVD chamber can have a dedicated exhaust source and pressure within each PVD chamber can be independently controlled.

In some embodiments, a pressure and/or relative pressure in each of the two or more PVD chambers can be independently controlled. In other embodiments, the process gas composition and/or relative gas composition in each of the two or more PVD chambers can be independently controlled.

Magnetron 1216 can be or include, for example, a magnet array. Magnetron 1216 can be rotating (e.g., about a center axis 1232 as shown) or scanning (not shown), and/or fixed (not shown); a larger array may be used if fixed for full face erosion of the target. Magnetron 1216 may suitably be cooled—e.g., using chilled water, helium, or the like.

PVD chamber 1200 includes a target power supply 1234 to provide power to target 1212 to generate plasma 1220. Target power supply 1234 can be a DC power supply (shown), a pulsed-DC power supply, a HiPIMS power supply, an RF power supply and/or combinations thereof. Target power supply 1234 can be suitably connected to a controller, such as a controller described herein. Power from target power supply 1234 can be provided to a backing plate 1236 that is coupled to target 1212.

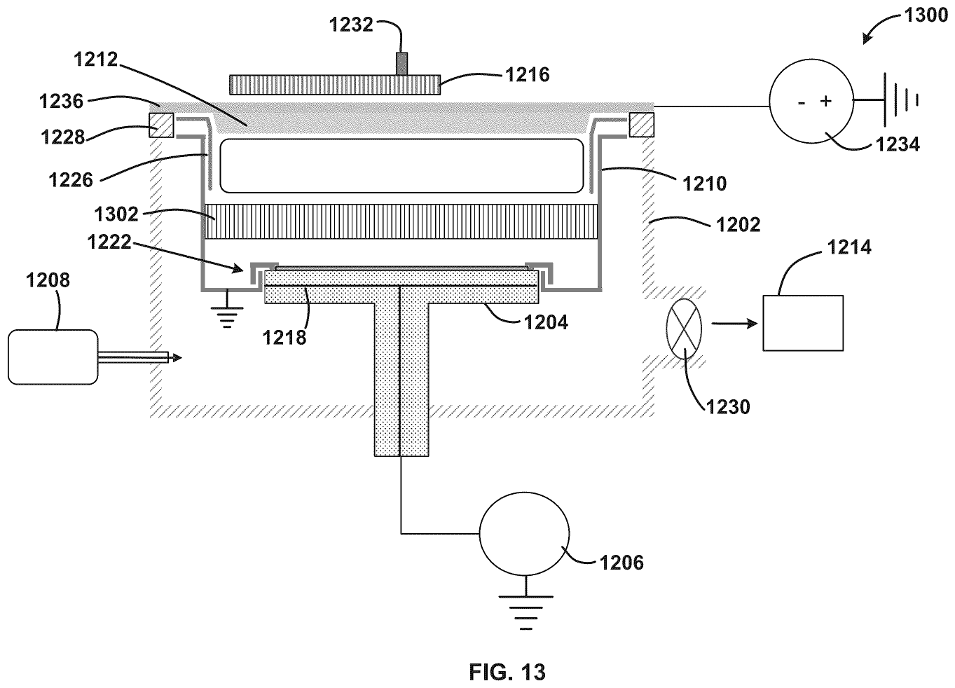

FIG. 13 illustrates a PVD chamber 1300 in accordance with additional examples of the disclosure. PVD chamber 1300 is similar to PVD chamber 1200, except PVD chamber 1300 includes a collimator 1302.

Collimator 1302 can be disposed in between target 1212 and susceptor 1204 and be substantially parallel to a top surface of susceptor 1204. Collimator 1302 may be used to improve step coverage of material deposited onto a substrate surface.

Collimator 1302 includes a plurality (e.g., an array) of apertures. The apertures can include, for example, a spherical, hexagonal, or the like cross section. An aspect ratio (depth relative to opening) of the apertures can be, for example, greater than or equal to 0.5 or greater than or equal to 1. A layout of the apertures can be suitably chosen for desired filtering and across substrate/wafer uniformity.

In some cases, collimator 1302 may be biased to improve step coverage. In other cases, collimator 1302 may be grounded or may float. In accordance with examples of the disclosure, collimator 1302 can modulate angular distribution of sputtered flux and/or plasma species directed toward susceptor 1204 or a substrate thereon.

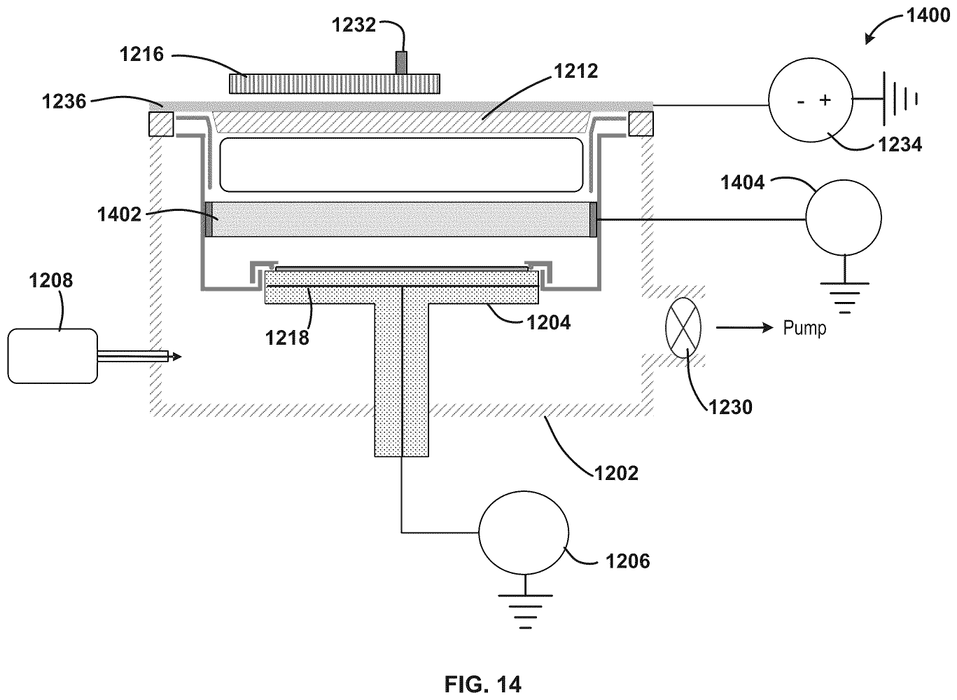

FIG. 14 illustrates a PVD chamber 1400 in accordance with additional examples of the disclosure. PVD chamber 1400 is similar to PVD chamber 1200, except PVD chamber 1400 includes one or more internal coil(s) 1402 coupled to a power source 1404.

Coil(s) 1402 can be single and/or multi-turn coil(s). The coil material can be the same material as target 1212 material.

Power source 1404 can be configured to provide power to coil(s) 1402 to increase a plasma density. By way of example, power source 1404 can provide power having a frequency of 2 MHz or 13.56 MHz or higher frequency. A frequency of power source 1404 may be desirably different than a frequency of other power sources of a system (e.g., different frequency than substrate bias power supply 1206 and/or a different phase to avoid crosstalk). Power source 1404 can be coupled to a controller, such as a controller described herein.

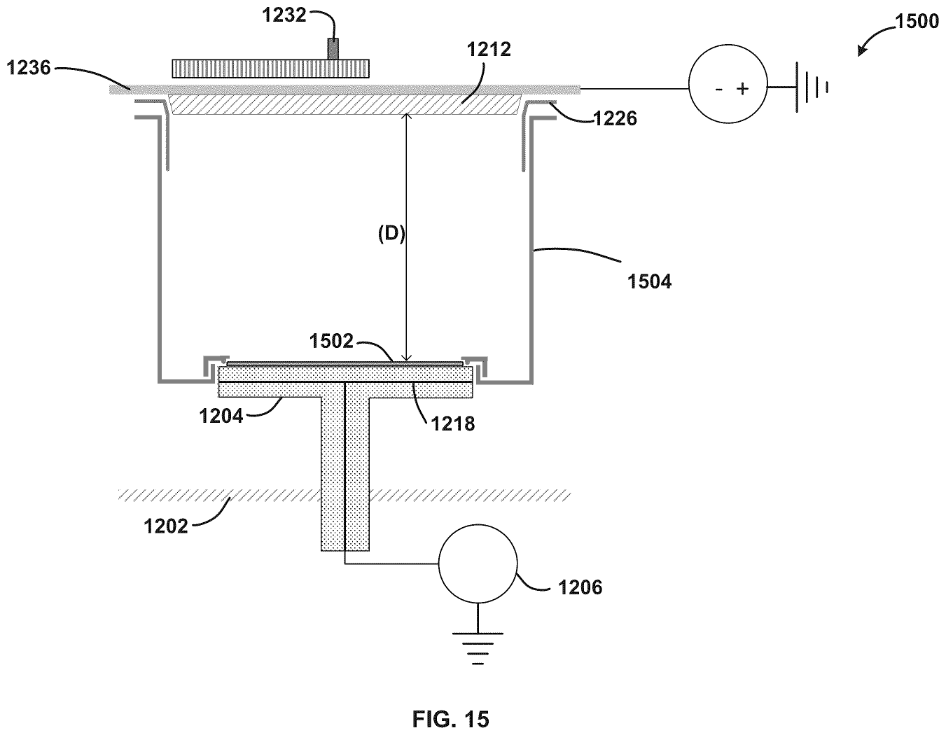

FIG. 15 illustrates a PVD chamber 1500 in accordance with additional examples of the disclosure. PVD chamber 1500 is similar to PVD chamber 1200, except PVD chamber 1500 is configured as a long-throw PVD reactor. In this configuration, a distance D between a substrate 1502 on susceptor 1204 and target 1212 is greater than or equal to a diameter of substrate 1502, or greater than or equal to 1.5× or 2× the diameter of substrate 1502. Distance D can be suitably increased to effect tighter angular distribution of sputtered flux to substrate 1502 for improved step coverage.

To accommodate the increased spacing between susceptor 1204 and target 1212, a longer shield 1504 may be employed. Shield 1504 can otherwise be the same or similar to shield 1210.

In some cases, PVD chamber 1500 can include a chamber spacer (not shown) and the associated shield change can enable increased target/susceptor spacing for processing substrates.

FIG. 12 to FIG. 15 illustrate various configurations of PVD chambers in accordance with examples of the disclosure. Such configurations can be combined in any combination within a PVD module and/or within a system. Further, various features of PVD chambers can be combined. For example, a long throw configuration (FIG. 15) can be combined with a collimator, as illustrated in FIG. 13; a long throw configuration (FIG. 15) can be combined with a coil, as illustrated in FIG. 14; a collimator configuration (FIG. 13) can be combined with a coil (FIG. 14); or a long throw configuration (FIG. 15) can be combined with a collimator (FIG. 13) and a coil (FIG. 14). Other combinations are also feasible.

During operation of systems and/or PVD chambers described herein, various materials can be deposited onto the substrate. As noted above, chambers within a module can include different materials, such that multiple layers and/or composite materials can be deposited within a PVD module. A thickness of a file deposited can range from, for example, approximately 0.5 nm to 500 nm. In some embodiments, the thickness is less than 5 nm. In other embodiments, the thickness is between 10 nm and 1 mm. In other embodiments, the thickness is between 1 mm and 100 mm.

Although exemplary embodiments of the present disclosure are set forth herein, it should be appreciated that the disclosure is not so limited. For example, although the assemblies, systems, and methods are described in connection with various specific configurations, the disclosure is not necessarily limited to these examples. Various modifications, variations, and enhancements of the exemplary systems and modules set forth herein may be made without departing from the spirit and scope of the present disclosure.

The subject matter of the present disclosure includes all novel and nonobvious combinations and subcombinations of the various systems, modules, components, and configurations, and other features, functions, acts, and/or properties disclosed herein, as well as any and all equivalents thereof.

1. A system comprising:
a load lock chamber;
a physical vapor deposition (PVD) module comprising two or more PVD chambers;
a substrate handling chamber;
at least one additional module; and
a robot within the substrate handling chamber, the robot comprising an arm comprising one or more end effectors, each end effector configured to receive one or more substrates; and
a controller configured to cause the robot to move the one or more substrates from the load lock chamber and between the physical vapor deposition module and the at least one additional module.

2. The system of claim 1, wherein the at least one additional module comprises a surface modification module.

3. The system of claim 2, wherein the at least one additional module comprises a degas module, a preclean module, or both.

4. The system of claim 3, wherein the degas module comprises two or more degas chambers.

5. The system of claim 4, wherein the degas module comprises a turbomolecular pump, a cryopump, or both coupled to the two or more degas chambers.

6. The system of claim 3, wherein the surface modification module comprises a preclean chamber

7. The system of claim 6, wherein the preclean chamber comprises a capacitively coupled plasma chamber or an inductively coupled plasma chamber.

8. The system of claim 6, wherein the preclean chamber comprises a chiller to cool a cooling fluid.

9. The system of claim 8, wherein the preclean chamber comprises a susceptor having a conduit to receive the cooling fluid to cool a substrate to a temperature of at least 0° C. or lower.

10. The system of claim 1, wherein the two or more PVD chambers comprise a sputtering chamber.

11. The system of claim 1, wherein each of the two or more PVD chambers comprises a shield.

12. The system of claim 1, wherein the two or more PVD chambers comprise a DC sputter reactor, a pulsed DC sputter reactor, a HiPIMS (high power impulse magnetron sputtering) sputter reactor, an RF sputter reactor, or any combination thereof.

13. The system of claim 1, wherein each of the two or more PVD chambers is coupled to an exhaust source.

14. The system of claim 13, wherein a pressure and/or gas composition in each of the two or more PVD chambers is independently controlled.

15. The system of claim 1, further comprising a cool down module, wherein the controller is further configured to cause the robot to move the one or more substrates to and from the cool down module.

16. The system of claim 1, further comprising a metrology module, wherein the controller is further configured to cause the robot to move the one or more substrates to and from the metrology module.

17. A physical vapor deposition (PVD) module comprising:
a first PVD chamber comprising a first target material and a first susceptor;
a second PVD chamber comprising a second target material and a second susceptor;
a shield between the first PVD chamber and the second PVD chamber;
a first power supply to provide power to the first target; and
a second power supply to provide power to the second target.

18. The PVD module of claim 17, wherein the first PVD chamber comprises a collimator.

19. The PVD module of claim 17, wherein a distance between a substrate on the first susceptor and the first target is greater than or equal to a diameter of the substrate.

20. The PVD module of claim 17, wherein the first PVD chamber and the second PVD chamber are coupled to an exhaust source, and wherein a pressure and/or gas composition within the first PVD chamber and a pressure and/or gas composition within the second PVD chamber are independently controlled.

21. The PVD module of claim 17, wherein first susceptor comprises a cooling fluid conduit.
